(19) United States
(12) Patent Application Publication
(10) Pub. No.: US 2003/0170972 A1
(43) Pub. Date: Sep. 11, 2003

(54) Dynamic solder attach

(76) Inventor: Scott L. Kirkman, Menlo Park, CA (US)

Correspondence Address: BLAKELY, SOKOLOFF, TAYLOR & ZAFMAN LLP, Seventh Floor, 12400 Wilshire Boulevard, Los Angeles, CA, 90025-1030, US

(21) Appl. No.: 10/092,239

(22) Filed: Mar. 6, 2002

(51) Int. Cl. H01L 21/44

(52) U.S. Cl. 438/612

(57) ABSTRACT

Disclosed are novel methods and apparatus for efficiently providing dynamic solder attach, in part, to decrease the affects of thermal variations. In an embodiment, a spacer provides a gap between a semiconductor package and a device, an attachment material is disposed between the device and the semiconductor package, and an environmental control device provides an appropriate environment to activate the attachment material. In another embodiment, while the attachment material is substantially activated, the spacer increases the gap between the semiconductor package and the device to elongate the attachment material in a plane substantially perpendicular to the device and the semiconductor package. In yet a different embodiment, the elongated attachment material assumes a substantially hourglass shape.

### FIELD OF INVENTION

The subject of this application relates generally to the field of electronic device manufacturing and, more particularly, to improving solder attach applications.

### BACKGROUND OF INVENTION

As integrated circuit fabrication technology improves, manufacturers are able to integrate additional functionality onto a single silicon substrate. As the number of these functionalities increases, however, so does the number of components on a single chip. Additional components add additional signal switching, in turn, creating more heat. The additional heat adds to the already-existing thermal expansion issues.

Thermal expansion differences between a semiconductor device and a system motherboard have been a fundamental problem facing the semiconductor industry. Generally, a semiconductor package provides a device with electrical connection to the motherboard, heat dissipation, and mechanical and environmental protection. As part of the mechanical protection function, the package can provide a solution to the thermal mismatch issue between the device and the motherboard.

During normal operation, the device is expected to survive a fairly wide range of temperature fluctuations. While undergoing these fluctuations, if the device expands and contracts at one rate while the package and/or board move at vastly different rates, a great deal of stress can be generated within the combined structure. These stresses can produce failures within the components themselves or at any of the interfaces between these components.

An attach design that is quickly gaining acceptance by semiconductor industry is flip chip. Flip chip technology generally places chips on circuit boards face side down. The chips are then connected to circuits by small “bumps” of solder. This configuration eliminates wire bonding and allows shorter interconnections between circuits and components to provide more robust, lighter, smaller, and faster networks. An ever-increasing number of semiconductor manufacturers are adapting flip chip designs, in part, because of the increasing number of I/Os employed in devices.

As the number of I/Os for each device increases, there is correspondingly less space to place the I/Os around the periphery of a device. To solve this problem, many semiconductor manufacturers are moving to full area array or partial area array I/O designs. Such designs, in turn, increase the need for the advantages provided by a flip chip process.

Unfortunately, no method of device to package attach seems to be more sensitive to thermal expansion problems than flip chip. This sensitivity is, in part, based on the flip chip technology requiring a small bump size, which brings the die very close to the package. This lack of distance combined with the rigid nature of the solder results in a high stress interconnect when the CTE is not matched. In addition, as the device size grows, the problem becomes worse because as the distance from neutral point grows, the relative movement (or strain) increases.

A classic question facing the package designers is: Should the package thermal expansion be matched to the device or to the motherboard. Both approaches have been employed with varying degrees of success throughout the industry. If the package is matched more closely to the device, then the attachment method between the board and the package must be compliant enough to absorb the movement. Typical solutions include sockets, pins, solder columns, and interposers. All of these can provide a compliant interface either with the materials themselves or sufficient distance (i.e. stand off) between the package and board. Each of these methods, however, has drawbacks.

In the case of sockets, there exists a significant cost versus electrical performance trade off. A socket, which adds marginally to the overall costs, can significantly degrade electrical performance. In addition, these sockets usually require pins to be placed on the package, adding cost and process steps. Conversely, a socket which does not degrade electrical performance or require pins can cost as much as the package itself. In addition, these types of sockets typically require a great deal of force to be placed on the package to ensure good socket contact. This can limit the mechanical and thermal design solutions.

Solder columns provide another solution by providing the proper stand off with good electrical connection, but are difficult to process and limited in supplier base. Another approach is to make use of solders with different melting, or re-flow, temperatures. Components within the solder attach method can be designed with higher melting solders. These can act as a stand off to maintain a greater distance between the package and motherboard because they would not melt and collapse during the normal board mount process. This method adds complications to the assembly process.

The interposer solution is relatively untested and is inherently undesirable because it, like sockets, adds a component to the assembly process and bill of materials.

If the package is matched thermally to the board, then the attachment method between device and package must absorb the inherent stresses. Presently, this method is achieved by using an epoxy, or epoxy like material, called an under-fill which is dispensed between the device and the package after the flip chip attach is completed. The under-fill acts to absorb stresses. This method, however, can be employed successfully for relatively small devices. Unfortunately, as the devices grow larger, even the under-fill cannot reduce the stresses to non-lethal levels. A great deal of process and material development will be required to achieve success with a larger die.

### SUMMARY OF INVENTION

The present invention includes novel methods and apparatus to provide dynamic solder attach, in part, to decrease the affects of thermal variations. In an embodiment, an apparatus is disclosed. The apparatus includes a semiconductor package, a device to be attached to the semiconductor package, a spacer to provide a gap between the semiconductor package and the device, an attachment material disposed between the device and the semiconductor package, and an environmental control device to provide an appropriate environment to activate the attachment material.

In another embodiment, while the attachment material is substantially activated, the spacer increases the gap between the semiconductor package and the device to elongate the attachment material in a plane substantially perpendicular to the device and the semiconductor package.

In yet a different embodiment, the elongated attachment material assumes a substantially hourglass shape.

In various embodiments, the apparatus may further include any of the following:

a stopper to limit the increase of the gap once a desired size of the increased gap is reached;

a locking device to lock in the spacer once a desired size of the increased gap is reached;

a brake to maintain the gap at a desired size;

a computing device to actuate the brake; and/or

an aligner to align the semiconductor package and the device.

In a different embodiment, a novel method is disclosed. The method includes providing a spacer to control a gap between a semiconductor package and a device, providing attachment material between the device and the semiconductor package, positioning the device and the semiconductor package adjacent to each other to provide substantial contact between the device and the semiconductor package via the attachment material, providing an appropriate environment to activate the attachment material, and utilizing the spacer to increase the gap between the semiconductor package and the device while the attachment material is substantially activated.

In a further embodiment, the attachment material is elongated in a plane substantially perpendicular to the device and the semiconductor package.

In yet another embodiment, the elongated attachment material assumes a substantially hourglass shape.

In yet a different embodiment, the attachment material conducts electricity.

In a certain embodiment, the method further includes actuating a brake to maintain the gap at a desired size.

### BRIEF DESCRIPTION OF DRAWINGS

The present invention may be better understood and its numerous objects, features, and advantages made apparent to those skilled in the art by reference to the accompanying drawings in which:

FIG. 1A illustrates an exemplary partial cross-sectional view of a device 100 in accordance with an embodiment of the present invention;

FIG. 1B illustrates an exemplary partial cross sectional view of the device 100 of FIG. 1A after the solder balls 106 are elongated;

FIG. 2A illustrates an exemplary partial cross sectional view of a device 200 in accordance with an embodiment of the present invention;

FIG. 2B illustrates an exemplary partial cross sectional view of the device 200 of FIG. 2A after heat is applied to put the solder balls 106 in there reflow state;

FIG. 3A illustrates an exemplary partial cross sectional view of a device 300 in accordance with an embodiment of the present invention;

FIG. 3B illustrates an exemplary partial cross sectional view of the device 300 after the lifting mechanism 130 increases the distance between the motherboard 102 and the semiconductor package 104;

FIG. 4 illustrates an exemplary partial cross sectional view of a device 400 in accordance with an embodiment of the present invention; and

FIG. 5 illustrates an exemplary partial cross sectional view of a device 500 in accordance with an embodiment of the present invention.

The use of the same reference symbols in different drawings indicates similar or identical items.

### DETAILED DESCRIPTION

In the following description, numerous details are set forth. It will be apparent, however, to one skilled in the art, that the present invention may be practiced without these specific details. In other instances, well-known structures and devices are shown in block diagram form, rather than in detail, in order to avoid obscuring the present invention.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

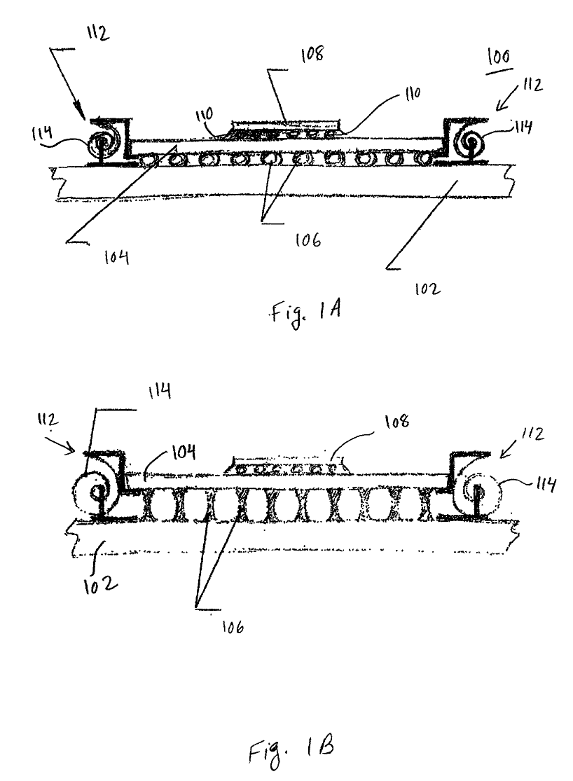

FIG. 1A illustrates an exemplary partial cross-sectional view of a device 100 in accordance with an embodiment of the present invention. A motherboard 102 is attached to a semiconductor package 104 via solder balls 106. As illustrated, a semiconductor device 108 is attached to the semiconductor package 104 via solder balls 110. The semiconductor device 108 can be any semiconductor device including an integrated circuit, a processor, an application specific integrated chip (ASIC), and the like. It is envisioned that the semiconductor device 108 may be attached to the semiconductor package 104 utilizing a flip chip technique. A lifting mechanism 112 is attached to the semiconductor package 104. The lifting mechanism 112 can utilize a spring 114 to increase the distance between the semiconductor package 104 and the motherboard 102 at a given point in time. It is envisioned that the lifting mechanism 112 can utilize a bimetallic spring 114. The bimetallic spring 114 can be designed such that it would raise the semiconductor package 104 once the solder balls 106 are in their molten state. The spring can also be designed such that it would expand at a given rate depending on a given temperature and/or rate of temperature change applied to the spring.

FIG. 1B illustrates an exemplary partial cross sectional view of the device 100 of FIG. 1A after the solder balls 106 are elongated. The spring 114 lifts the semiconductor package 104 as shown in FIG. 1B by expansion. It is envisioned that the solder balls 106 may assume an hourglass form as illustrated in FIG. 1B. The heat required to put the solder balls 106 in their molten state, or other wise to provide reflow, can be provided by putting the device 100 in, for example, furnace or on a belt furnace which may in some embodiments employ different zones for heating. The temperature of each zone and the speed of the belt movement can be adjusted for an optimal case. Additionally, the temperature that the device 100 is exposed to may be appropriately chosen to burn off any fluxes which may be present for cleaning organics or otherwise for improving the soldering process.

Generally solder may have a propensity to stick to metallic surfaces. As such metal plated pads may be utilized on the contact points where the solder balls meet a device such as the semiconductor package 104. These pads may also be plated with nickel and/or gold for better adhesion and to reduce corrosion. The propensity to stick to the metallic surfaces also helps in achieving the hourglass shape of the solder balls 106 illustrated in FIG. 1B. It is believed that an hourglass shape solder joint can be one of the most reliable structures during temperature cycling. Thus, such a structure may decrease the effects of thermal expansion substantially.

Moreover, it is envisioned that the expanded spring of 114 of FIG. 1B can be locked in place to provide sufficient distance between the semiconductor package 104 and the motherboard 102. The locking may also assist the rigidity of the solder balls during the cooling stage by avoiding undesirable movements in certain directions.

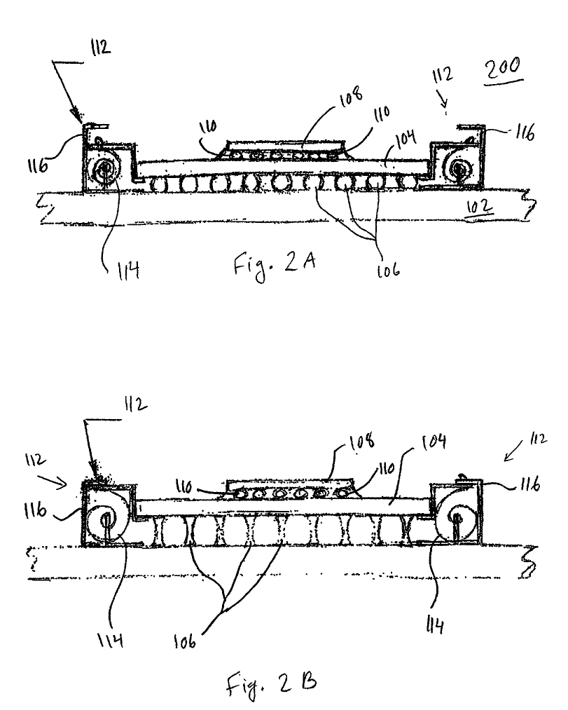

FIG. 2A illustrates an exemplary partial cross sectional view of a device 200 in accordance with an embodiment of the present invention. As illustrated, the lifting mechanism 112 of FIG. 2A further includes a hard stop 116. As the spring 114 increases the distance between the semiconductor package 104 and the motherboard 102, the hard stop 116 limits the expansion of the spring 114 beyond a desirable point. This desirable point may be chosen, for example, based on the desired distance between the devices being attached. The stop point may also depend on the amount of solder being utilized and the appropriate curvature to be achieved for the hourglass shape.

FIG. 2B illustrates an exemplary partial cross sectional view of the device 200 of FIG. 2A after heat is applied to put the solder balls 106 in there reflow state. In FIG. 2B, the hard stop 116 limits the movement achieved by expansion of the spring 114. It is further envisioned that the lifting mechanism 112 of FIG. 2B also provide for locking the lifting mechanism once a desired distance is reached. As shown in FIG. 2B, this can be achieved by utilizing a mechanical locking design, such as the illustrated hard stop 116. The locking in place of the lifting mechanism 112 will prevent any spacing decrease between the semiconductor package 104 and the motherboard 102 after the spring 114 has performed its task during reflow.

It is envisioned that any lifting apparatus discussed herein may utilize numerous devices to achieve the lifting. Examples of other lifting apparatus include a spring (with any shape including cylindrical, spiral, conical, flat, u-shaped, and the like), a hydraulic mechanism, a screw, a gear, a wheel, a semi-solid (in an embodiment, epoxy like) material, which expands with temperature then solidifies to not only set the proper stand off but acts as an under-fill, any device that may be utilized to provide lifting, or any combination thereof. It is envisioned that a gear may be utilized that would engage teeth present on the objects being separated. Alternatively, a gear may be installed on the objects being separated with teeth on a bracket. With respect to wheels, they may be selected from material such that sufficient friction would be present for separating the objects. It is further envisioned that any of the lifting apparatus may be externally controlled, utilizing techniques including those discussed herein.

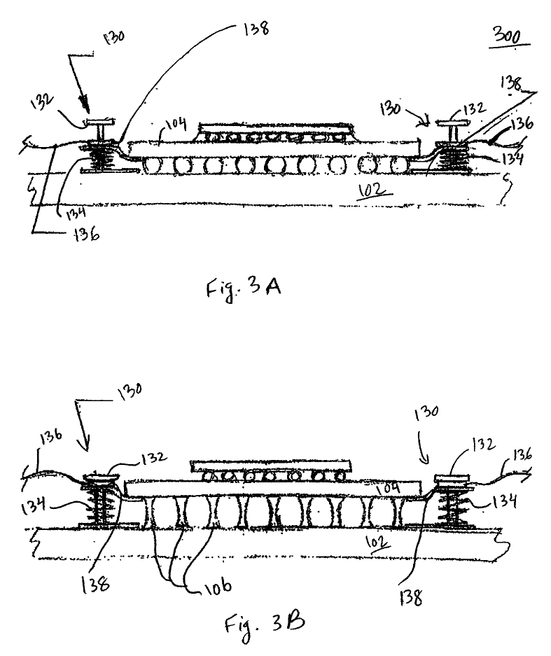

FIG. 3A illustrates an exemplary partial cross sectional view of a device 300 in accordance with an embodiment of the present invention. The device 300 utilizes a lifting mechanism 130. The lifting mechanism 130 includes a hard stop 132, a brake 138, a control connection 136, and a lifting device 134. The lifting device 134 may be any type of a device capable of lifting including those discussed herein. The brake 138 may be a secondary brake or a brake under external control through, for example, the control connection 136. As a secondary brake, the brake 138 will ensure that no movement is provided until a desired time and/or distance is reached. In some embodiments, the control connection 136 may be wiring for external temperature or time control. In certain embodiments, the brake 138 may be externally actuated and/or be temperature sensitive. Also, wireless communication (utilizing electromagnetic waves such as radio waves, infrared, visible light, ultraviolet, X rays, gamma rays, and the like) may be employed to provide communication and/or control of elements within the device 300.

FIG. 3B illustrates an exemplary partial cross sectional view of the device 300 after the lifting mechanism 130 increases the distance between the motherboard 102 and the semiconductor package 104. As illustrated in FIG. 3B, the lifting mechanism 130 has achieved a desired distance between the semiconductor package 104 and the motherboard 102 such that the solder balls 106 have achieved an hourglass shape. It is also envisioned that the brake 138 may be actuated under periodical and/or gradational control such that the distance between the package 104 and the motherboard 102 is controlled as a function of time and/or temperature. This can ensure that the solder balls 106 are given sufficient time to expand during the reflow, for example. It is also envisioned that finite element methods and/or fuzzy logic techniques can be utilized to ensure proper movement provided by any lifting apparatus. Any movement provided for herein can also be controlled and/or directed by a computing device such as a general purpose computer, a personal digital assistant (PDA), an embedded device, and the like.

In an embodiment, the computing device includes a Sun Microsystems computer utilizing a SPARC microprocessor available from several vendors (including Sun Microsystems of Palo Alto, Calif.). Those with ordinary skill in the art understand, however, that any type of computer system may be utilized to embody the present invention, including those made by Hewlett Packard of Palo Alto, Calif., and IBM-compatible personal computers utilizing Intel microprocessor, which are available from several vendors (including IBM of Armonk, N.Y.). Also, instead of a single processor, two or more processors (whether on a single chip or on separate chips) can be utilized to provide speedup in operations.

The computing device may also employ a network interface to provide communication capability with other computer systems on a same local network, on a different network connected via modems and the like to the present network, or to other computers across the Internet. In various embodiments, the network interface can be implemented in Ethernet, Fast Ethernet, wide-area network (WAN), leased line (such as T1, T3, optical carrier 3 (OC3), and the like), digital subscriber line (DSL and its varieties such as high bit-rate DSL (HDSL), integrated services digital network DSL (IDSL), and the like), time division multiplexing (TDM), asynchronous transfer mode (ATM), satellite, cable modem, and FireWire.

Moreover, the computing device may utilize operating systems such as Solaris, Windows (and its varieties such as NT, 2000, XP, ME, and the like), HP-UX, Unix, Berkeley software distribution (BSD) Unix, Linux, Apple Unix (AUX), and the like. Also, it is envisioned that in certain embodiments, the computing device is a general purpose computer capable of running any number of applications such as those available from companies including Oracle, Siebel, Unisys, Microsoft, and the like.

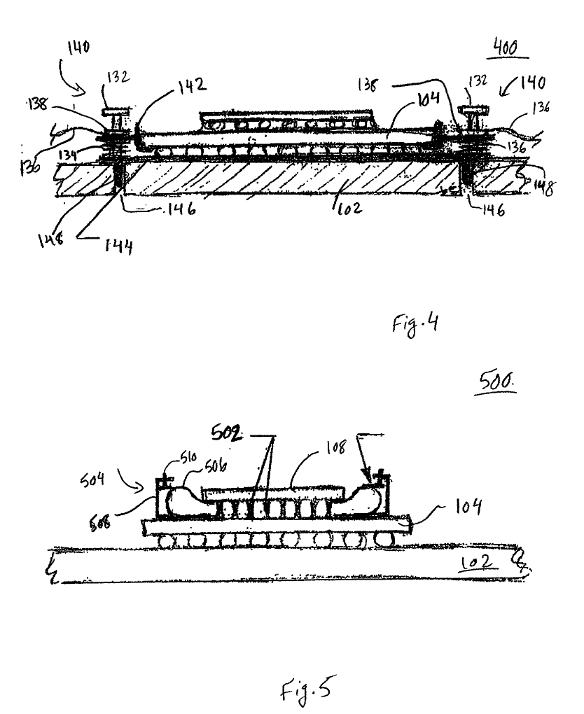

FIG. 4 illustrates an exemplary partial cross sectional view of a device 400 in accordance with an embodiment of the present invention. The device 400 includes a lifting mechanism 140. The lifting mechanism 140 includes a lifting aligner 142, a hard stop 132, a lifter 134, a control mechanism 136, a stop 138, and alignment pins 148. It is envisioned that the lifting mechanism 140 may be any lifting apparatus discussed herein. The device 400 may also include the illustrated alignment holes 146 in the motherboard 132. In some embodiments, the alignment may be provided by the semiconductor package and the lifting may be applied to the motherboard or any device being attached. As illustrated, the alignment pins 148 may be inserted in the alignment holes 146 of the motherboard 102. The combination of the alignment brackets 142, alignment holes 146, and alignment pins 148 provide the device 400 with proper alignment between the semiconductor package 104 and the motherboard 102. This is especially important as packages increase in size and the solder balls decrease in size. The device 400 may also include an optional expansion frame 144 which can be aligned with the alignment pins 148 and the alignment holes 146. The expansion frame 144 shown can be mounted to the motherboard 102 through alignment pins 148 and/or alignment holes 146. It is envisioned that utilizing alignment techniques discussed herein will stabilize the semiconductor package in the X, Y, and theta directions.

FIG. 5 illustrates an exemplary partial cross sectional view of a device 500 in accordance with an embodiment of the present invention. The device 500 includes a lifting mechanism 504 which can control the distance between the semiconductor package 104 and the semiconductor device 108 during reflow. The lifting mechanism 504 includes a spring 506 a stop 508 and a locking mechanism 510. It is envisioned that the lifting mechanism 504 may be any lifting apparatus discussed herein. As illustrated in FIG. 5, the locking mechanism 510 may be engagingly attached to the spring 506. The device 500 can provide lifting to the semiconductor device itself during the device attach reflow process. Thus, elongated solder joints are provided during reflow to reduce stress on the structures.

The foregoing description has been directed to specific embodiments. It will be apparent to those with ordinary skill in the art that modifications may be made to the described embodiments, with the attainment of all or some of the advantages. For example, the techniques discussed herein may be applied to any items being attached together. Also, the techniques discussed herein may be applied with other attachment material including glues (such as chemical, thermal, combinations thereof, and the like), welds, and the like. Therefore, it is the object of the appended claims to cover all such variations and modifications as come within the spirit and scope of the invention.

What is claimed is:

1. A method of manufacturing an electronic device with reduced susceptibility to damage caused by thermal variations, the method comprising:
providing a semiconductor package;
providing a device to be attached to the semiconductor package;
providing a spacer to provide a gap between the semiconductor package and the device;
providing attachment material between the device and the semiconductor package;
positioning the device and the semiconductor package adjacent to each other to provide substantial contact between the device and the semiconductor package via the attachment material;
providing an appropriate environment to activate the attachment material; and
utilizing the spacer to increase the gap between the semiconductor package and the device while the attachment material is substantially activated,
wherein the attachment material is elongated in a plane substantially perpendicular to the device and the semiconductor package.

2. The method of claim 1 wherein the elongated attachment material assumes a substantially hourglass shape.

3. The method of claim 1 wherein the device is selected from a group comprising a board, an integrated circuit, a processor, and an ASIC.

4. The method of claim 1 wherein the spacer utilizes a lifting apparatus selected from a list comprising a spring, a hydraulic mechanism, a screw, a gear, a semi-solid material, and a wheel.

5. The method of claim 4 wherein a portion of the spring assumes a shape selected from a group comprising cylindrical, spiral, conical, flat, and u-shaped.

6. The method of claim 1 wherein a size of the increased gap is dependent on the amount of attachment material.

7. The method of claim 1 wherein a size of the increased gap is dependent on a shape to be provided by the attachment material.

8. The method of claim 1 wherein the act of increasing the gap is done gradually.

9. The method of claim 1 wherein the attachment material conducts electricity.

10. The method of claim 1 wherein the attachment material is selected from a group comprising thermal glue, chemical glue, weld, and solder.

11. The method of claim 1 further including stopping the act of increasing the gap by utilizing a stopping mechanism once a desired size of the increased gap is reached.

12. The method of claim 1 further including locking in the spacer once a desired size of the increased gap is reached.

13. The method of claim 1 further including utilizing a brake to maintain the gap at a desired size.

14. The method of claim 13 wherein the brake maintains the gap while the attachment material is still inactive.

15. The method of claim 13 wherein the brake is externally actuated.

16. The method of claim 15 wherein the brake is externally actuated based on temperature.

17. The method of claim 15 wherein the brake is externally actuated by utilizing a computing device.

18. The method of claim 17 wherein the computing device is selected from a group comprising a computer, a PDA, and an embedded device.

19. The method of claim 1 wherein the appropriate environment is a molten state of the attachment material.

20. The method of claim 1 further including aligning the semiconductor package and the device at least while the gap is being increased.

21. The method of claim 20 wherein the aligning is achieved by providing alignment holes and pins.

22. The method of claim 20 wherein the aligning is achieved by providing an expansion frame.

23. The method of claim 1 wherein the attachment material meets the device and the semiconductor package at a plurality of pads with metallic surfaces.

24. The method of claim 23 wherein the metallic surfaces of the plurality of pads are made of material selected from a group comprising gold and nickel.

25. An apparatus comprising:
a semiconductor package;
a device to be attached to the semiconductor package;
a spacer coupled to the semiconductor package and the device to provide a gap between the semiconductor package and the device;
attachment material disposed between the device and the semiconductor package, the device and the semiconductor package positioned adjacent to each other to provide substantial contact between the device and the semiconductor package via the attachment material; and
an environmental control device to provide an appropriate environment to activate the attachment material,
wherein, while the attachment material is substantially activated, the spacer increases the gap between the semiconductor package and the device to elongate the attachment material in a plane substantially perpendicular to the device and the semiconductor package.

26. The apparatus of claim 25 wherein the elongated attachment material provides an attach with reduced susceptibility to damage caused by thermal variations.

27. The apparatus of claim 25 wherein the environmental control device is selected from a group comprising a furnace and a belt furnace.

28. The apparatus of claim 27 wherein a speed of the belt furnace is adjusted for optimum provision of an attach with reduced susceptibility to damage caused by thermal variations.

29. The apparatus of claim 25 wherein the environmental control device employs multiple temperature zones.

30. The apparatus of claim 25 wherein the elongated attachment material assumes a substantially hourglass shape.

31. The apparatus of claim 25 wherein the device is selected from a group comprising a board, an integrated circuit, a processor, and an ASIC.

32. The apparatus of claim 25 wherein the spacer utilizes a lifting apparatus selected from a list comprising a spring, a hydraulic mechanism, a screw, a gear, a semi-solid material, and a wheel.

33. The apparatus of claim 32 wherein a portion of the spring assumes a shape selected from a group comprising cylindrical, spiral, conical, flat, and unshaped.

34. The apparatus of claim 25 wherein the attachment material conducts electricity.

35. The apparatus of claim 25 wherein the attachment material is selected from a group comprising thermal glue, chemical glue, weld, and solder.

36. The apparatus of claim 25 further including a stopper to limit the increase of the gap once a desired size of the increased gap is reached.

37. The apparatus of claim 25 further including a locker to lock in the spacer once a desired size of the increased gap is reached.

38. The apparatus of claim 25 further including a brake to maintain the gap at a desired size.

39. The apparatus of claim 38 wherein the brake maintains the gap while the attachment material is still inactive.

40. The apparatus of claim 39 wherein the brake is externally actuated.

41. The apparatus of claim 39 further including a computing device to actuate the brake.

42. The apparatus of claim 41 wherein the computing device is selected from a group comprising a computer, a PDA, and an embedded device.

43. The apparatus of claim 25 further including alignment holes and pins to align the semiconductor package and the device at least while the gap is being increased.

44. The apparatus of claim 25 further including an expansion frame to align the semiconductor package and the device at least while the gap is being increased.

45. The apparatus of claim 25 further including a plurality of pads with metallic surfaces to provide improved contact between the attachment material at least one of the items from a group comprising the device and the semiconductor package.

46. The apparatus of claim 45 wherein the metallic surfaces of the plurality of pads are made of material selected from a group comprising gold and nickel.

47. An apparatus comprising:
a semiconductor package;
a device to be attached to the semiconductor package;
a spacer means to provide a gap between the semiconductor package and the device;
attachment means disposed between the device and the semiconductor package; and
environmental control means to provide an appropriate environment to activate the attachment means.

48. The apparatus of claim 47 wherein, while the attachment means is substantially activated, the spacer means increases the gap between the semiconductor package and the device to elongate the attachment means in a plane substantially perpendicular to the device and the semiconductor package.

49. The apparatus of claim 47 wherein the elongated attachment means assumes a substantially hourglass shape.

50. The apparatus of claim 47 further including stopping means to limit the increase of the gap once a desired size of the increased gap is reached.

51. The apparatus of claim 47 further including locking means to lock in the spacer once a desired size of the increased gap is reached.

52. The apparatus of claim 46 further including brake means to maintain the gap at a desired size.

53. The apparatus of claim 51 further including computing means to actuate the brake.

54. The apparatus of claim 46 further including alignment means to align the semiconductor package and the device.

55. An article of manufacture comprising:
a machine readable medium that provides instructions that, if executed by a machine, will cause the machine to perform operations including:
actuating a spacer to provide a gap between a semiconductor package and a device;
providing attachment material between the device and the semiconductor package;
positioning the device and the semiconductor package adjacent to each other to provide substantial contact between the device and the semiconductor package via the attachment material;
providing an appropriate environment to activate the attachment material; and
utilizing the spacer to increase the gap between the semiconductor package and the device while the attachment material is substantially activated,
wherein the attachment material is elongated in a plane substantially perpendicular to the device and the semiconductor package.

56. The article of claim 54 wherein the elongated attachment material assumes a substantially hourglass shape.

57. The article of claim 54 wherein the device is selected from a group comprising a board, an integrated circuit, a processor, and an ASIC.

58. The article of claim 54 wherein the attachment material conducts electricity.

59. The article of claim 54 wherein the operations further include actuating a brake to maintain the gap at a desired size.
